(19) United States
(12) Patent Application Publication
(10) Pub. No.: US 2026/0347544 A1
(43) Pub. Date: Nov. 5, 2026

(54) CURABLE COMPOSITION AND COATED SUPERSTRATE

(71) Applicant: CANON KABUSHIKI KAISHA, Tokyo (JP)

(72) Inventors: Kui XU, Austin, TX (US); Timothy Brian Stachowiak, Austin, TX (US); Fen Wan, Austin, TX (US); Weijun Liu, Cedar Park, TX (US); Sophia A. Ortega-Reidel, Austin, TX (US)

(21) Appl. No.: 19/189,007

(22) Filed: Apr. 24, 2025

(51) Int. Cl. C08G 77/04; B05D 1/00; B05D 3/04; B05D 5/08; B05D 7/02; C09D 183/04

(52) U.S. Cl. CPC C08G 77/045; B05D 1/005; B05D 3/046; B05D 5/08; B05D 7/02; C09D 183/04; B05D 2203/30; B05D 2401/10; B05D 2518/12; C08G 2150/00

(57) ABSTRACT

A curable composition can comprise at least one reactive polysilsesquioxane, at least one dihydroxysilane, and a solvent, wherein the at least one reactive polysilsesquioxane comprises functional groups; and the at least one dihydroxysilane has a structure of formula (1):

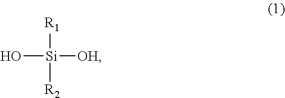

wherein R₁ is C₂-C₂₀-alkyl, cycloalkyl, or fluorine-containing alkyl, and R₂ is methyl or ethyl or propyl. The curable composition can be adapted for forming a coated superstrate for use in Inkjet Adaptive Planarization.

### FIELD OF THE DISCLOSURE

The present disclosure relates to a curable composition and a superstrate coated with the curable composition for Inkjet Adaptive Planarization.

### BACKGROUND

Inkjet Adaptive Planarization (IAP) requires the use of a superstrate having a high flatness and a super-hydrophobic and super-oleophobic working surface. Such working surfaces typically comprise a polymeric coating layer applied by spin-coating, wherein the coating layer contains as majority a perfluorinated polymer. Because of the high material costs and technical challenges of handling perfluorinated polymers, an intermediate layer is often included underneath the perfluorinated layer. Other disadvantages of using perfluorinated polymers as coating material are the limited solubility of these polymers in non-fluorinated solvents (non-fluorinated solvents being desired because of their low costs), as well as problems during filtering at filter pore sizes in the range of 10 nm and below.

There exists a need to improve spin-coated superstrates, wherein the hydrophobic coating layer has low material costs and allows simplified and efficient handling, such as improved solubility in low-cost solvents, easy processability, and less environmental concerns.

### SUMMARY

In one embodiment, a curable composition can comprise at least one reactive polysilsesquioxane, at least one dihydroxysilane, and a solvent, wherein the at least one reactive polysilsesquioxane comprises functional groups; and the at least one dihydroxysilane has a structure of formula (1):

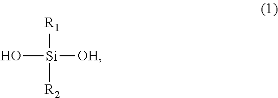

wherein R₁ is C₂-C₂₀-alkyl, cycloalkyl, or fluorine-containing alkyl, and R₂ is methyl or ethyl or propyl.

In one aspect of the curable composition, the amount of the at least one dihydroxysilane can be at least 1 wt % and not greater than 10 wt % based on the total weight of the polysilsesquioxane and the dihydroxysilane. In a particular aspect, the amount of the at least one dihydroxysilane may be not greater than 5 wt % based on the total weight of the polysilsesquioxane and the dihydroxysilane.

In a further aspect of the curable composition, the at least one dihydroxysilane can include a fluorine-containing dihydroxysilane and a dihydroxysilane not containing fluorine.

In yet another aspect of the curable composition, the at least one dihydroxysilane may not comprise fluorine.

In a particular aspect of the curable composition, the at least one dihydroxysilane can include isobutyl(methyl)silanediol, dihydroxy-methyl-(3,3,3-trifluoropropyl)silane, or a combination thereof.

In one aspect of the curable composition, the functional groups of the reactive polysilsesquioxane can include hydroxyl groups.

In a certain aspect of the curable composition, the reactive polysilsesquioxane can be a polymerization product of at least one first Si-containing monomer having a structure of formula (3) and at least one second Si-containing monomer having a structure of formula (4):

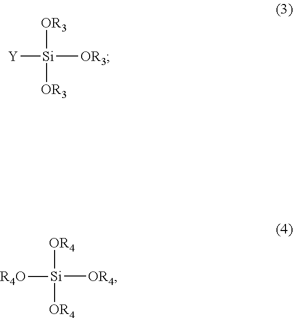

wherein R₃ and R₄ is C₁-C₆ alkyl, and Y is alkyl, or aryl, or aryl-alkyl, or fluorine-containing alkyl.

In a certain aspect of the curable composition, the reactive polysilsesquioxane can be free of fluorine.

In another aspect of the curable composition, the weight percent ratio of the at least one reactive polysilsesquioxane to the at least one dihydroxysilane can be at least 10:1.

In a further aspect of the curable composition, the amount of the solvent may be at least 50 wt % based on the total weight of the curable composition.

In a certain aspect, the solvent of the curable composition can include propylene glycol methyl ether (PGME), propylene glycol methyl ether acetate (PGMEA), γ-butyrolactone (GBL), methanol, ethanol, or isopropanol.

In another aspect, the viscosity of the curable composition may be not greater than 50 mPa·s.

In one aspect of the curable composition, the amount of the reactive polysilsesquioxane can be at least 0.5 wt % and not greater than 20 wt % based on the total weight of the curable composition.

In one embodiment, a coated superstrate can comprise: a superstrate blank having a first surface and a second surface, the first surface and the second surface being opposite to each other; and a coating layer directly overlying the first surface of the superstrate blank, wherein the coating layer is a cured coating of a curable composition, the curable composition comprising at least one reactive polysilsesquioxane, at least one dihydroxysilane, and a solvent, wherein the at least one reactive polysilsesquioxane comprises functional groups; and the at least one dihydroxysilane has a structure of formula (1):

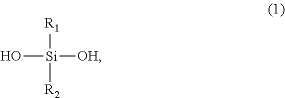

wherein R₁ is C₂-C₂₀-alkyl, cycloalkyl, or fluorine-containing alkyl, and R₂ is methyl, ethyl or propyl.

In one aspect of the coated superstrate, the thickness of the coating layer can be at least 1 nm and not greater than 100 nm.

In another aspect of the coated superstrate, the water contact angle to the coating layer can be at least 70 degrees and not greater than 140 degrees.

In yet a further aspect of the coated superstrate, surface energy of the coating layer can be at least 25 mN/m and not greater than 50 mN/m.

In a further embodiment, a system for planarizing a formable material can comprise: the above-described coated superstrate coupled to a superstrate holder; and a formable material positioned on a substrate, wherein the coated superstrate is positioned above a top surface of the formable material and configured for planarizing the top surface of the formable material.

In another embodiment, a method of forming a coated superstrate can comprise: providing a superstrate blank having a first surface and a second surface, the first surface being opposite to the second surface; applying by spin-coating on the first surface of the superstrate blank a liquid layer of a curable composition; and curing the curable composition to form a coating layer, wherein the curable composition comprises at least one reactive polysilsesquioxane, at least one dihydroxysilane, and a solvent, wherein the at least one reactive polysilsesquioxane comprises functional groups; and the at least one dihydroxysilane has a structure of formula (1):

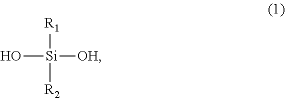

wherein R₁ is C₂-C₂₀-alkyl, cycloalkyl, or fluorine-containing alkyl, and R₂ is methyl, or ethyl, or propyl.

### BRIEF DESCRIPTION OF THE DRAWINGS

Embodiments are illustrated by way of example and are not limited in the accompanying figure.

FIG. 1 includes a line drawing illustrating a section of a side-view of a coated superstrate according to one embodiment.

FIG. 2 includes a line drawing illustrating a system for planarizing a formable material including a coated superstrate according to one embodiment.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a curable composition comprising at least one reactive polysilsesquioxane, at least one dihydroxysilane, and a solvent. The at least one reactive polysilsesquioxane can comprise functional groups, and the at least one dihydroxysilane can have a structure of formula (1):

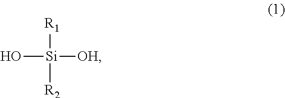

with R₁ being C₂-C₂₀-alkyl, cycloalkyl, or fluorine-containing alkyl, and R₂ being methyl, or ethyl, or propyl.

In a certain aspect, the reactive polysilsesquioxane (PSS) can comprise structure-units of formula (2):

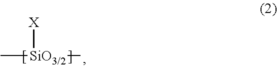

with X being alkyl, or aryl, or aryl-alkyl, a functional group, fluorine-containing alkyl, or any combination thereof. In a particular aspect, X can be C₁-C₅ alkyl, and the functional group may be hydroxyl.

As used herein, the term “reactive” in combination with “polysilsesquioxane” means that the polysilsesquioxane contains functional groups suitable to be involved in polymerization and cross-linking reactions with the dihydroxysilane and/or further additives.

As further used herein, the variety of options for X of the structure unit of formula (2) of the reactive polysilsequioxane (PSS) means that the PSS may contain different structure units of formula (2), wherein the structure units can differ with regard to X. For example, the PSS can contain as majority of the structure units alkyl for X, while a smaller percentage may include hydroxyl for X.

In one embodiment, the PSS can be a polymerization product made by hydrolysis and polycondensation of at least one first Si-containing monomer having a structure of formula (3), and at least one second Si-containing monomer having a structure of formula (4):

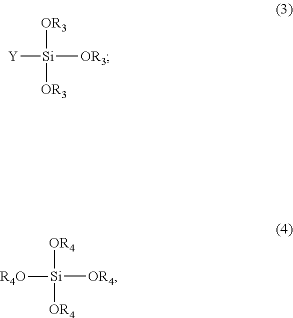

wherein R₃ and R₄ can be C₁-C₈ alkyl, and Y can be alkyl, glycidyl-alkyl, or aryl, or arylalkyl, or fluorine-containing alkyl.

In one aspect, the first Si-containing monomer can be a C₁-C₈ alkyltrimethoxysilane, or phenyltrimethoxysilane, or a fluorine-containing C₁-C₈-alkyltrimethoxysilane. Specific non-limiting examples of the first Si-containing monomer can be methyltrimethoxysilane, or isobutyltrimethoxysilane, or phenyltrimethoxysilane, or 1H,1H,2H,2H-nonafluorohexyl-trimethoxysilane, or any combination thereof.

In another aspect, the second Si-containing monomer can be tetraethyl orthosilicate (TEOS).

In a particular aspect, the reactive polysilsesquioxane can be formed by at least two different monomers falling under formula 3 (the first Si-containing monomer); and one monomer falling under formula 4 (the second Si-containing monomer).

In a further aspect, the amount of the first Si-containing monomer for forming the reactive polysilsesquioxane (PSS) can be at least 20 mol % based on the total molar amount of monomers forming the PSS, or at least 25 mol %, or at least 30 mol %, or at least 35 mol %, or at least 40 mol %, or at least 45 mol %, or at least 50 mol %, or at least 55 mol %, or at least 60 mol %. In another aspect, the amount of the second Si-containing monomer may be not greater than 70 mol %, or not greater than 60 mol %, or not greater than 55 mol %.

In a particular aspect, the second Si-containing monomer for forming the PSS can be TEOS in an amount from 30 mol % to 55 mol %.

In one aspect, the reactive PSS can comprise functional groups selected from the group of glycidyl groups, or hydroxyl groups, or carboxylic acid groups, or alkoxysilane groups, or vinyl groups, or acrylate groups, or any combinations thereof. In a particular aspect, the reactive PSS may comprise hydroxyl groups.

In a particular aspect, the reactive PSS can contain structure units of formula (2), wherein X can be —(CH₂)ₘ—CₙF₂ₙ₊₁, with n being 4-18, and m being 0-4. In a particular certain aspect, n can be 4-10 and m can be 1-2.

In one embodiment, the reactive polysilsesquioxane (PSS) of the curable composition may be essentially free of fluorine. As used herein, essentially free of fluorine means that an amount of fluorine is not greater than 0.5 wt % based on the total weight of the polysilsesquioxane. In a further aspect, the reactive PSS can be free of fluorine.

In a further embodiment, the reactive PSS can be free of fluorine and may comprise structure units of formula (2), wherein X is a fluorine-free hydrophobic residue, for example, X can be C₄-C₁₈-alkyl, or C₄-C₁₈-isoalkyl, or phenyl, or phenyl-C₄-C₁₈ alkyl, or phenyl-C₄-C₁₈-isoalkyl. The hydrophobic character of the formed PSS can be balanced by using a combination of monomers, wherein some monomers can contain for X the above-described hydrophobic rest, and other monomers can have for X a hydrophilic rest.

In a further aspect, the molecular weight of the reactive polysilsesquioxane can be at least 500 g/mol, or at least 1000 g/mol, or at least 2000 g/mol, or at least 5000 g/mol, or at least 10,000 g/mol, or at least 20,000 g/mol, or at least 50,000 g/mol. In another aspect, the molecular weight of the polysilsesquioxane may be not greater than 100,000 g/mol, or not greater than 50,000 g/mol, or not greater than 10,000 g/mol, or not greater than 5,000 g/mol, or not greater than 1000 g/mol.

The amount of the reactive PSS can be at least 0.5 wt % based on the total weight of the curable composition, or at least 1 wt %, or at least 1.3 wt %, or at least 2 wt %, or at least 5 wt %, or at least 7 wt %, or at least 10 wt %. In another aspect, the amount of the reactive PSS may be not greater than 20 wt %, or not greater than 15 wt %, or not greater than 10 wt %, or not greater than 5 wt %, or not greater than 3 wt %, or not greater than 2 wt %, or not greater than 1.5 wt % based on the total weight of the curable composition.

In another embodiment, the dihydroxysilane of formula (1) can have for R1 C₂-C₁₀ alkyl, or C₂-C₅ alkyl, or fluorine-containing alkyl, and for R₂ a methyl, ethyl, or propyl.

In one aspect, the at least one dihydroxysilane can comprise fluorine. A non-limiting example for a fluorine-containing dihydroxysilane can be dihydroxy-methyl-(3,3,3-trifluoropropyl)silane.

In a further aspect, the curable composition can comprise at least two different dihydroxysilanes. In a particular aspect, the at least two different dihodroxysilanes can include one dihydroxysilane being free of fluorine, and one dihydroxysilane comprising fluorine. For example, the curable composition may include as dihydroxysilanes the combination of isobutyl(methyl)silanediol and dihydroxy-methyl-(3,3,3-trifluoropropyl)silane.

In another particular aspect, the at least one dihydroxysilane can be essentially free of fluorine. As used herein, being essentially free of fluorine means that an amount of fluorine in the dihydroxysilane is not greater than 1 wt % based on the total weight of the dihydroxysilane, or not greater than 0.5 wt %, or not greater than 0.1 wt %. In a particular certain aspect, the at least one dihydroxysilane can be free of fluorine.

The amount of the at least one dihydroxysilane can be at least 1 wt % based on the total weight of the at least one dihydroxysilane and the at least one reactive polysilsesquioxane, or at least 2 wt %, or at least 3 wt %. In another aspect, the amount of the dihydroxysilane may be not greater than 10 wt %, or not greater than 5 wt %, or not greater than 4 wt %, or not greater than 3 wt % based on the total weight of the at least one dihydroxysilane and the at least one reactive polysilsesquioxane.

In one embodiment, the weight percent ratio of the at least one reactive PSS to the at least one dihydroxysilane can be at least at least 10:1, or at least 15:1, or at least 20:1, or at least 30:1; or at least 45:1, or at least 70:1, or at least 80:1, or at least 90:1, or at least 95:1. In another aspect, the ratio of PSS to dihydroxysilane may be not greater than 99.5:1, or not greater than 99:1, or not greater than 90:1, or not greater than 80:1, or not greater than 60:1.

In one aspect, the reactive polysilsesquioxane can be free of fluorine and the dihydroxysilane can be free of fluorine.

The amount of the solvent in the curable composition can be at least 40 wt % based on the total weight of the curable composition, or at least 50 wt %, or at least 60 wt %, or at least 70 wt % or at least 80 wt %, or at least 85 wt %, or at least 90 wt %, or at least 92 wt %, or at least 95 wt %. In one aspect, the amount of the solvent may be not greater than 99 wt %, or not greater than 97 wt %, or not greater than 95 wt %, or not greater than 93 wt %, or not greater than 90 wt %, or not greater than 85 wt %, or not greater than 80 wt %, or not greater than 70 wt % based on the total weight of the curable composition.

The solvent of the curable composition is not limited to a specific solvent, as long as it can dissolve the at least one reactive PSS and the at least one dihydroxysilane of the curable composition. Non-limiting examples of suitable solvents of the curable composition can be ethyl acetoacetate (EAA), ethyl lactate (EL), cyclohexanone, propylene glycol methyl ether (PGME), propylene glycol methyl ether acetate (PGMEA), propylene glycol methyl ether (PGME), γ-butyrolactone (GBL), methanol, ethanol, or isopropanol.

The curable composition can further include a cross-linking catalyst (also called herein inter-changeable polymerization catalyst or polymerization initiator). In aspects, the cross-linking catalyst can be a phase transfer catalyst, a thermal acid generator, a thermal base generator, or a photoacid generator, or a photo-base generator.

In a particular aspect, the catalyst can be benzyltriethylammonium chloride. In another particular aspect, the cross-linking catalyst can be a thermal acid generator. Non-limiting examples of a thermal acid generator can be a triarylsulfonium salt, or a dialkylphenylsulfonium salt, or a diazeniumdiolate, or a sulfonate ester, or a ketoxime ester, or an imide, or a N-sulfonyloxaziridine, or a benzoin ether, or a sulfonylhydrazide.

In one embodiment, the curable composition of the present disclosure can be essentially free of particles, for example being essentially free of pigment particles. As used herein, being essentially free of particles means that the curable composition contains not more than 50 particles per ml having a size of 200 nm or greater, or not more than 50 particles per ml having a size of 150 nm or greater, or not more than 50 particles per ml having a size of 100 nm or greater, or not more than 50 particles per ml having a size of 50 nm or greater, or not more than 50 particles per ml having a size of 30 nm or greater.

In another embodiment, the viscosity at 23 °C of the curable composition can be not greater than 100 mPa·s, or not greater than 50 mPa·s, or not greater than 40 mPa·s, or not greater than 35 mPa·s, or not greater than 30 mPa·s, or not greater than 25 mPa·s, or not greater than 20 mPa·s. In another aspect, the coating composition can have a viscosity of at least 5 mPa·s, or at least 10 mPa·s, or at least 15 mPa·s, or at least 20 mPa·s. As used herein, the viscosities relate to Brookfield viscosities, measured with a Brookfield viscometer at 23 °C.

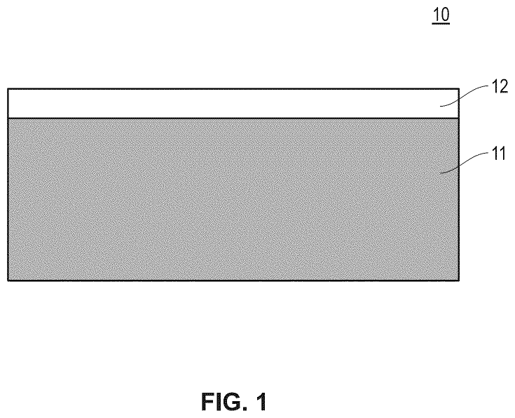

FIG. 1 includes an illustration of a side view of a coated superstrate (10), containing a superstrate blank (11) and a solid polymeric coating layer (12) directly overlying the superstrate blank (11).

In one embodiment, the coating layer (12) can be a cured coating of the above-described curable composition.

In one embodiment, the coating layer (12) can be formed by applying a liquid layer of the above-described curable composition of the present disclosure via spin-coating on a first outer surface of a superstrate blank (11). The liquid layer can be cured by heating the coated superstrate in the presence of a cross-linking catalyst.

In one aspect, the curing temperature can be at least 80 °C, or at least 100 °C, or at least 130 °C, or at least 150 °C, or at least 180 °C. In another aspect, the curing temperature may be not greater than 300 °C, or not greater than 250 °C, or not greater than 220 °C.

The amount of the cross-linking catalyst in the curable composition can be at least 0.00001 wt % based on the total weight of the curable composition, or at least 0.0001 wt %, or at least 0.001 wt %, or at least 0.01 wt %, or at least 0.1 wt %. In one aspect, the amount of the thermal acid generator may be not greater than 0.5 wt % based on the total weight of the curable composition, or not greater than 0.1 wt %, or not greater than 0.05 wt %.

In one embodiment, before coating the superstrate blank with the curable composition of the present disclosure, the curable composition can be filtered through a filter having a pore size of not greater than 0.1 microns, or not greater than 0.05 microns, or not greater than 0.02 microns, or not greater than 0.01 microns in order to remove particles.

In a certain aspect, an average thickness of the coating layer (12) can be at least 1 nm, or at least 5 nm, or at least 10 nm, or at least 20 nm, or at least 50 nm, or at least 100 nm, or at least 200 nm, or at least 300 nm, or at least 500 nm, or at least 1,000 nm. In another aspect, the average thickness of the coating layer (12) may be not greater than 10,000 nm, or not greater than 5,000 nm, or not greater than 2,000 nm, or not greater than 1,000 nm, or not greater than 500 nm, or not greater than 200 nm, or not greater than 100 nm, or not greater than 50 nm. In a particular aspect, the thickness of the coating layer (12) may be at least 10 nm and not greater than 100 nm.

Based on the fluorine content of the polysilsesquioxane and/or dihodroxysilane, and the amount of these ingredients in the curable composition, the fluorine content of the formed polymeric solid coating layer (12) after curing can be at least 0.001 wt % based on the total weight of the coating layer, or at least 0.01 wt %, or at least 0.1 wt %, or at least 1 wt %. In another aspect, the fluorine content of the formed coating layer may be not greater than 5 wt % based on the total weight of the coating layer, or not greater than 1 wt %, or not greater than 0.1 wt %, or not greater than 0.01 wt %.

In one embodiment, the water contact angle of the coating layer (12) can be at least 70°, or at least 75°, or at least 80°, or at least 85°, or at least 90°. In a further aspect, the water contact angle may be not greater than 140°, or not greater than 120°, or not greater than 110°, or not greater than 100°, or not greater than 90°.

In a further aspect, the coating layer (12) can have a surface free energy (SFE) of at least 25 mN/m, or at least 28 mN/m, or at least 30 mN/m, or at least 35 mN/m, or at least 40 mN/m. In another aspect, the SFE of the cured layer may be not greater than 50 mN/m, or not greater than 45 mN/m, or not greater than 40 mN/m, or not greater than 38 mN/m. In a particular aspect, the SFE can be at least 28 mN/m and not greater than 38 mN/m.

In yet another aspect, the refractive index of the coating layer (12) at a wavelength of 248 nm can be at least 1.3, or at least 1.35, or at least 1.40, or at least 1.45. In another aspect, the refractive index of the coating layer at 248 nm may be not greater than 1.75, or not greater than 1.65, or not greater than 1.55.

In a further aspect, the refractive index of the coating layer (12) at a wavelength of 633 nm may be at least 1.3, or at least 1.35, or at least 1.40, or at least 1.45. In another aspect, the refractive index of the coating layer at 633 nm may be not greater than 1.8, or not greater than 1.7, or not greater than 1.60.

In a further embodiment, the material of the superstrate blank can be a variety of materials. Non-limiting examples of materials can include a glass-based material, silicon, a spinel, a fused-silica, quartz, an organic polymer, a fluorocarbon polymer, or any combination thereof. The glass-based material can include soda lime glass, borosilicate glass, alkali-barium silicate glass, quartz glass, aluminosilicate glass, or synthetic fused-silica.

In a particular aspect, the coated superstrate can be transparent (meaning that both the superstrate and coating are transparent) to a selected actinic radiation and this radiation being used for curing a formable material, for example, to cure a resist during planarization at a certain UV light wave range.

In a certain embodiment, the coating layer (12) can be a single-layer coating. In another certain embodiment, the coating layer (12) can be a multi-layer coating.

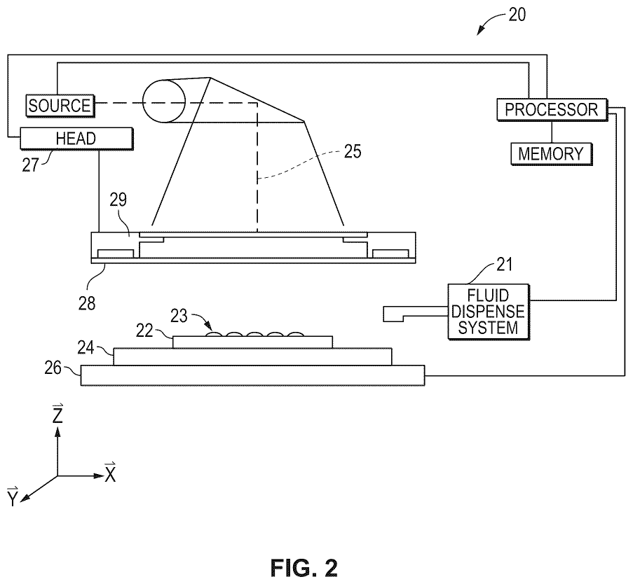

Referring to FIG. 2, a system (20) in accordance with an embodiment described herein can be used to planarize a formable material (23) on a substrate (22) using the coated superstrate (28) of the present disclosure. The coated superstrate (28) can be positioned spaced-apart from the substrate (22).

The substrate (22) may be coupled to a substrate holder (24), for example, to a chuck. The chuck may be any chuck including vacuum, pin-type, groove-type, electrostatic, electromagnetic, or the like. The substrate (22) and substrate holder (24) may be further supported by a stage (26). The stage (26) may provide translating or rotational motion along the X-, Y-, or Z-directions.

The coated superstrate (28) can be used to planarize a formable material deposited on a substrate (22). The coated superstrate (28) can be coupled to a superstrate holder (29). The coated superstrate (28) may be both held by and its shape modulated by the superstrate holder (29). The superstrate holder (29) may be configured to hold the superstrate (28) within a chucking region. The superstrate holder (29) can be configured as vacuum, pin-type, groove-type, electrostatic, electromagnetic, or another similar holder type. In one embodiment, the superstrate holder (29) can include a transparent window within the body of the superstrate holder (29).

The system (20) can further include a fluid dispense system (21) for depositing a formable material (23) on the surface of the substrate (22). The formable material (23) can be positioned on the substrate (22) in one or more layers using techniques such as droplet dispense, spin-coating, dip coating, chemical vapor deposition (CVD), physical vapor deposition (PVD), thin film deposition, thick film deposition, or combinations thereof. The formable material (23) can be dispensed upon the substrate (22) before or after a desired volume is defined between the superstrate (28) and the substrate (22). The formable material (23) can include one or more polymerizable monomers and/or oligomers and/or polymers that can be cured using actinic radiation and/or heat.

It has been surprisingly found that curable compositions containing a reactive polysilsesquioxanes and a dihydroxysilane of formula (1) in a ratio of at least 10:1 can lead to cured polymeric coating layers (12) having an excellent hydrophobicity. Such coatings can be a very cost-efficient replacement of expensive super-hydrophobic and super oleophobic fluoropolymer coatings, such as, for example, Cytop, in IAP processing.

### EXAMPLES

The following non-limiting examples illustrate the concepts as described herein.

### Example 1

A first series of curable compositions was prepared by combining different weight percent ratios of a polysilsesquioxane (PSS1) and a fluorine-free dihydroxysilane (DHS-1) in the solvent PGME. Each curable composition further contained benzyltriethylammonium chloride as curing catalyst.

The PSS1 was made by combining 20 mol % glycidylpropyl trimethoxysilane, 40 mol % tetraethoxysilane, and 40 mol % methyltrimethoxysilane (conducting hydrolysis and condensation). The obtained PSS1 was dissolved in PGME to form a 1.4 wt % PSS1 base solution for further use. To the PSS1 base solution was further added 0.01 wt % of the curing catalyst benzyltriethylammonium chloride.

As dihydroxysilane was used isobutyl(methyl)silanediol (DHS-1), which was made in house by the hydrolysis of isobutyldimethoxymethylsilane. The DHS-1 was also dissolved in PGME to form a base solution containing 1.4 wt % of the DHS-1.

Curable compositions S1, S2, and S3 were prepared by combining the PSS-1 base solution and the DHS-1 base solution to reach different ratios of PSS-1 to DHS-1 (see Table 1, wherein PSS-1 and DHS-1 stand for wt % of the base solutions respectively). Thereafter, the obtained curable compositions were stirred at room temperature (23 °C) overnight followed by filtering through a 0.1 micron pore size PTFE filter. The viscosities of the curable compositions after filtering were between 1 mPa-s and 10 mPa-s measured with the Brookfield method at 23 °C.

Coating layers were prepared by applying 8 ml of the curable compositions on a silicon wafer having a diameter of 200 mm via spin-coating using a Cee® Spin Coater at a rotation speed of 1500 rpm for 60 seconds. Thereafter, the applied coating was cured at 205 °C for 90 seconds. Comparative coating layer C1 was prepared by using only the PSS-1 base composition for forming the coating layer, while comparative coating layer C2 was made using only the DHS-1 base composition. The thickness after curing of the obtained coating layers was between 20 nm and 50 nm. The coating layers were tested regarding the water contact angle and surface free energy.

A summary of the coating compositions and the measured water contact angles and the surface free energy of the coating layers (after curing the coating compositions) is shown in Table 1.

TABLE 1

| | | | | Water | Surface |
|---|---|---|---|---|---|
| | PSS-1 | DHS-1 | Wt % Ratio | contact | Free Energy |
| Sample | [wt %] | [wt %] | PSS-1 / DHS-1 | angle [°] | [mJ/m²] |
| S1 | 99 | 1 | 99:1 | 76.7 | 37.8 |
| S2 | 98 | 2 | 98:2 | 78.5 | 36.7 |
| | | | (49:1) | | |
| S3 | 95 | 5 | 95:5 | 81.1 | 35.5 |
| | | | (19:1) | | |
| C1 | 100 | 0 | — | 69.5 | 42.1 |
| C2 | 0 | 100 | — | 86.0 | 30.0 |

It can be seen that already at a weight percent ratio PSS-1 to DHS-1 of 99:1, a large increase in the water contact angle was obtained of about 7 degrees if compared with layer C1. The water contact angle further increased to 81.1 degrees at a ratio of 95:5 (19:1).

While the water contact angle increased by the addition of small amounts of DHS-1, it can be seen from the data in Table 1 that the surface free energy decreased. These are desired effects. Not to be bound to theory, it is assumed that adding the dihydroxysilane to the reactive PSS can cause an increase in the hydrophobic character of the surface of a formed coating layer after curing the composition, which is shown by the decrease in SFE and increase of the water contact angle. The decreased surface energy and increased water contact angle may be due to the enrichment of hydrophobic dihydroxysilane at the surface of the cured coating layer.

### Measuring the Water Contact Angle

The water contact angles were measured with a Drop Master DM-701 contact angle meter made by Kyowa Interface Science Co. Ltd. (Japan).

For the testing, 2 ml of deionized water was added to the syringe, of which 2 μl sample per test was added by the machine to the surface of the coated and cured composition, herein called “coating layer,” on the wafer. Drop images were continuously captured by a CCD camera from the time the water or resist drop touched the layer surface. The contact angle was automatically calculated by the software based on the analysis of the images. The water contact angles presented in Tables 1 and 2 are the contact angles at a time of 3 seconds after the water drop was touching the surface of the wafer coating (also called herein coated superstrate).

### Measurement of the Surface Free Energy (SFE)

The SFE was measured with a Drop master DM-701 instrument, by measuring in a first measurement the contact angle of water and in a second measurement the contact angle of diiodomethane to the target surface (the photo-cured polymeric layers, which correspond to the material of the soft mold). The surface free energy was calculated based on both contact angle values using the Owens-Wendt method with the analysis software FAMAS installed in the Drop Mater DM-701 instrument.

### Measuring the Viscosity

The viscosities of the curable compositions were measured using a Brookfield Viscometer LVDV-II+Pro at 200 rpm, with a spindle size #18 and a spin speed of 100 rpm. For the viscosity testing, about 6-7 mL of sample liquid was added into the sample chamber, enough to cover the spindle head. The sample contained in the chamber was about 20 minutes equilibrated to reach the desired measuring temperature of 23 °C before the actual measurement was started. For all viscosity testing, at least three measurements were conducted and an average value was calculated.

### Example 2

A second series of curable compositions was prepared by combining the PSS-1 used in Example 1 with two dihydroxysilanes: the DHS-1 of example 1 and dihydroxy-methyl-(3,3,3-trifluoropropyl)silane (DHS-F).

The base solution of the PSS-1 was prepared the same way as in example 1 by dissolving 1.4 wt % of the reactive polysilsesquioxane in PGME and further adding 0.01 wt % of benzyltriethylammonium chloride as curing catalyst.

The dihydroxysilane base solution (DHS-2) was prepared by combining 90 mol % of the DHS-1 and 10 mol % of the dihydroxy-methyl-(3,3,3-trifluoropropyl)silane (DHS-F), such that the total amount of dihydroxysilane in the base solution was 1.4 wt %.

Curable compositions were prepared by combining the PSS-1 base solution and the DHS-2 base solution in different ratios, as shown in Table 2, wherein weight % stands for the weight amount of the base solutions used for preparing the curable compositions.

Coating layers were prepared from the curable compositions with different ratios of the base solutions PSS-1 and DHS-1 the same way as described in example 1, and the water contact angles and the surface free energy were measured on the surface of the cured coating layers.

TABLE 2

| | | | | Water | Surface |
|---|---|---|---|---|---|
| | PSS-1 | DHS-1 | Wt % Ratio | contact | Free Energy |
| Sample | [wt %] | [wt %] | PSS-1 / DHS-2 | angle [°] | [mJ/m²] |
| S4 | 99 | 1 | 99:1 | 77.2 | 36.5 |
| S5 | 98 | 2 | 98:2 | 82.2 | 33.2 |
| | | | (49:1) | | |
| S6 | 95 | 5 | 95:5 | 92.8 | 30.0 |
| | | | (19:1) | | |
| C1 | 100 | 0 | — | 69.5 | 42.1 |
| C3 | 0 | 100 | — | 95.7 | 29.2 |

The data in Table 2 show that including a minor amount of fluorine-containing dihydroxysilane as part of the dihydroxysilane can even further lower the surface free energy compared to the coating layer formed from the PSS-1 base solution alone, especially if the ratio of PSS-1 to DHS-2 was 95:5.

Table 3 is an extended table of Table 2, further showing the silicone content, the refractive indexes at 248 nm and 633 nm, and the thickness of the coating layers. The silicon content is a critical factor which can significantly influence the etching performance, particularly when the material is used for hardmask applications.

TABLE 3

| | | | | | Layer |
|---|---|---|---|---|---|
| | PSS-1 | DHS-2 | Si-content | Refractive index | thickness |
| Sample | [wt %] | [wt %] | [wt %] | 248 nm / 633 nm | [nm] |
| S4 | 99 | 1 | 33.01 | 1.490 / 1.413 | 57.5 |
| S5 | 98 | 2 | 32.88 | 1.490 / 1.412 | 57.3 |
| S6 | 95 | 5 | 32.50 | 1.489 / 1.410 | 56.9 |
| C1 | 100 | 0 | 33.14 | 1.494 / 1.416 | 58.2 |
| C3 | 0 | 100 | 20.25 | | |

The data in Table 3 show that the coating layers of samples S4, S5, and S6 are very similar in their silicon content if compared to the silicon content of layer C1 formed from the PSS-1 base solution. It is remarkable that when comparing the properties of comparative sample C1 and sample S6, while the silicon content is nearly the same (difference in silicone content is only 0.64 wt %), a strong decrease in the surface energy of 12.1 mN/m was obtained. Furthermore, there were only minor changes with regard to the refractive indexes of samples S4, S5, and S6 and comparative sample C1 at 248 nm and 633 nm.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any sub combination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A curable composition comprising at least one reactive polysilsesquioxane, at least one dihydroxysilane, and a solvent, wherein
the at least one reactive polysilsesquioxane comprises functional groups; and
the at least one dihydroxysilane has a structure of formula (1): 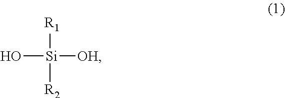
wherein R₁ is C₂-C₂₀-alkyl, cycloalkyl, or fluorine-containing alkyl, and R₂ is methyl or ethyl or propyl.

2. The curable composition of claim 1, wherein an amount of the at least one dihydroxysilane is at least 1 wt % and not greater than 10 wt % based on the total weight of the polysilsesquioxane and the dihydroxysilane.

3. The curable composition of claim 2, wherein the amount of the at least one dihydroxysilane is not greater than 5 wt % based on the total weight of the polysilsesquioxane and the dihydroxysilane.

4. The curable composition of claim 1, wherein the at least one dihydroxysilane includes a fluorine-containing dihydroxysilane and a dihydroxysilane not containing fluorine.

5. The curable composition of claim 1, wherein the at least one dihydroxysilane does not comprise fluorine.

6. The curable composition of claim 1, wherein the at least one dihydroxysilane includes isobutyl(methyl)silanediol, dihydroxy-methyl-(3,3,3-trifluoropropyl)silane, or a combination thereof.

7. The curable composition of claim 1, wherein the functional groups of the reactive polysilsesquioxane include hydroxyl groups.

8. The curable composition of claim 1, wherein the reactive polysilsesquioxane is a polymerization product of at least one first S1-containing monomer having a structure of formula (3) and at least one second S1-containing monomer having a structure of formula (4): 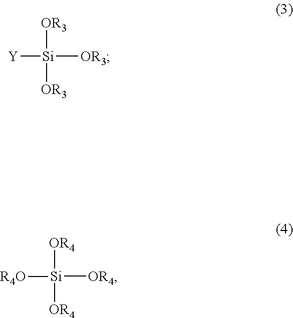
wherein R₁ and R₂ is C₁-C₆ alkyl, and X is alkyl, or aryl, or aryl-alkyl, or fluorine-containing alkyl.

9. The curable composition of claim 1, wherein the reactive polysilsesquioxane is free of fluorine.

10. The curable composition of claim 1, wherein a weight percent ratio of the at least one reactive polysilsesquioxane to the at least one dihydroxysilane is at least 10:1.

11. The curable composition of claim 1, wherein an amount of the solvent is at least 50 wt % based on the total weight of the curable composition.

12. The curable composition of claim 1, wherein the solvent includes propylene glycol methyl ether (PGME), propylene glycol methyl ether acetate (PGMEA), γ-butyrolactone (GBL), methanol, ethanol, or isopropanol.

13. The curable composition of claim 1, wherein a viscosity of the curable composition is not greater than 50 mPa·s.

14. The curable composition of claim 1, wherein an amount of the reactive polysilsesquioxane is at least 0.5 wt % and not greater than 20 wt % based on the total weight of the curable composition.

15. A coated superstrate comprising:
a superstrate blank having a first surface and a second surface, the first surface and the second surface being opposite to each other; and
a coating layer directly overlying the first surface of the superstrate blank,
wherein
the coating layer is a cured coating of a curable composition, the curable composition comprising at least one reactive polysilsesquioxane, at least one dihydroxysilane, and a solvent, wherein
the at least one reactive polysilsesquioxane comprises functional groups; and
the at least one dihydroxysilane has a structure of formula (1): 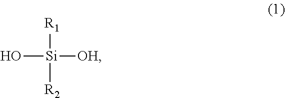
wherein R₁ is C₂-C₂₀-alkyl, cycloalkyl, or fluorine-containing alkyl, and R₂ is methyl, ethyl or propyl.

16. The coated superstrate of claim 15, wherein a thickness of the coating layer is at least 1 nm and not greater than 100 nm.

17. The coated superstrate of claim 15, wherein a water contact angle to the coating layer is at least 70 degrees and not greater than 140 degrees.

18. The coated superstrate of claim 15, wherein a surface energy of the coating layer is at least 25 mN/m and not greater than 50 mN/m.

19. A system for planarizing a formable material, comprising:
the coated superstrate of claim 15 coupled to a superstrate holder; and
a formable material positioned on a substrate,
wherein the coated superstrate is positioned above a top surface of the formable material and configured for planarizing the top surface of the formable material.

20. A method of forming a coated superstrate, comprising:
providing a superstrate blank having a first surface and a second surface, the first surface being opposite to the second surface;
applying by spin-coating on the first surface of the superstrate blank a liquid layer of a curable composition; and
curing the curable composition to form a coating layer,
wherein the curable composition comprises at least one reactive polysilsesquioxane, at least one dihydroxysilane, and a solvent, wherein
the at least one reactive polysilsesquioxane comprises functional groups; and
the at least one dihydroxysilane has a structure of formula (1): 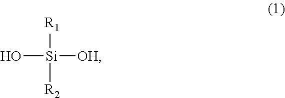
wherein R₁ is C₂-C₂₀-alkyl, cycloalkyl, or fluorine-containing alkyl, and R₂ is methyl, ethyl or propyl.
